(19) United States
(12) Patent Application Publication
(10) Pub. No.: US 2018/0139864 A1
(43) Pub. Date: May 17, 2018

(54) HEAT TRANSPORT DEVICE AND ELECTRONIC DEVICE

(71) Applicant: FUJITSU LIMITED, Kawasaki-shi (JP)

(72) Inventors: Nobuyuki HAYASHI, Yokohama (JP); Teru NAKANISHI, Isehara (JP); Takahiro KIMURA, Isehara (JP)

(73) Assignee: FUJITSU LIMITED, Kawasaki-shi (JP)

(21) Appl. No.: 15/869,468

(22) Filed: Jan. 12, 2018

Related U.S. Application Data
(63) Continuation of application No. PCT/JP2015/070620, filed on Jul. 17, 2015.

(51) Int. Cl. H05K 7/20; F25D 17/00

(52) U.S. Cl. CPC H05K 7/2039; F28D 15/02; F25D 17/00

(57) ABSTRACT

A heat transport device includes: a heat receiving member that receives heat; a heat dissipation member that dissipates heat; a coolant circulation path that includes a main flow portion in which coolant flows and split flow portions where part of the main flow portion is split into plural flow paths, and that causes coolant to circulate between the heat receiving member and the heat dissipating member; pumps that are provided to the respective split flow portions; and a bypass flow path that forms a bypass between the respective split flow portions on an outlet side of the pumps and the main flow portion.

### CROSS-REFERENCE TO RELATED APPLICATION

This application is a continuation application of International Application PCT/JP2015/070620 filed on Jul. 17, 2015, and designated the U.S., the entire contents of which are incorporated herein by reference.

### FIELD

The present disclosure relates to a heat transport device and an electronic device.

### BACKGROUND

Circulation systems exist in which two circulation pumps are connected in parallel in a flow path for a liquid coolant, and a three-way valve is attached to the discharge side of each pump. In such circulation systems, when one of the circulation pumps is stopped, the three-way valve shuts off a flow path at the side of the stopped circulation pump, such that only coolant discharged from the other circulation pump circulates through the cooling system.

Liquid cooling devices also exist in which two pumps are interposed in parallel between a tank and a coolant supply pipe leading to an electronic device, and a three-way valve is connected to discharge tubes of the two pumps. In such liquid cooling devices, when one pump fail, operation switches to the other pump such that coolant continues to be supplied to the electronic device.

### RELATED DOCUMENTS

### Related Patent Documents

Patent Document 1: Japanese Laid-Open Patent Application (JP-A) No. 2005-228237

Patent Document 2: Japanese Laid-Open Patent Application (JP-A) No. H04-245697

### SUMMARY

In one aspect, a heat transport device includes a heat receiving member that receives heat; a heat dissipation member that dissipates heat; a coolant circulation path that includes a main flow portion in which coolant flows and split flow portions where part of the main flow portion is split into plural flow paths, and that causes coolant to circulate between the heat receiving member and the heat dissipating member; pumps that are provided to the respective split flow portions; and a bypass flow path that forms a bypass between the respective split flow portions on an outlet side of the pumps and the main flow portion.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a perspective view illustrating an electronic device of a first exemplary embodiment.

FIG. 2 is a perspective view illustrating a state in which plural electronic devices of the first exemplary embodiment have been loaded onto a rack.

FIG. 3 is a plan view illustrating a heat receiving member of a cooling device of the first exemplary embodiment.

FIG. 4 is a front view illustrating the heat receiving member of the cooling device of the first exemplary embodiment.

FIG. 5 is a diagram illustrating the cooling device of the first exemplary embodiment.

FIG. 6 is an enlarged diagram illustrating the vicinity of a parallel pump section of the cooling device of the first exemplary embodiment.

FIG. 7 is an enlarged diagram illustrating the vicinity of the parallel pump section of the cooling device of the first exemplary embodiment.

FIG. 8 is a diagram illustrating one example of a joint member of the cooling device of the first exemplary embodiment.

FIG. 9 is a diagram illustrating another example of a joint member of the cooling device of the first exemplary embodiment.

FIG. 10 is an enlarged diagram illustrating the vicinity of a parallel pump section of a cooling device of a second exemplary embodiment.

FIG. 11 is an enlarged diagram illustrating the vicinity of a parallel pump section in a modified example of a cooling device of the second exemplary embodiment.

### DESCRIPTION OF EMBODIMENTS

Detailed explanation follows regarding a first exemplary embodiment, with reference to the drawings.

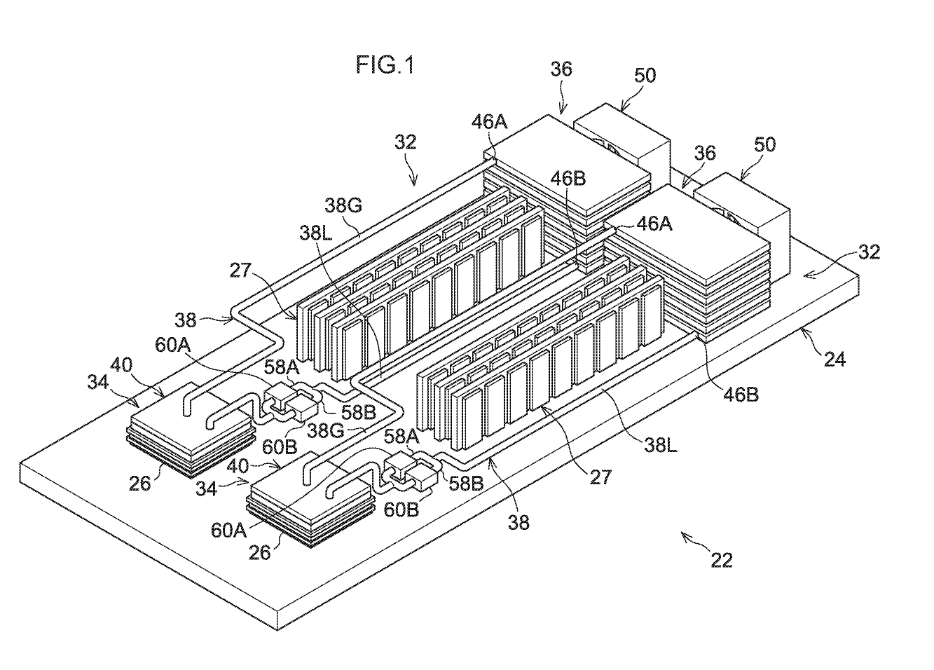

As illustrated in FIG. 1, an electronic device 22 includes a substrate 24. Electronic components 26 are mounted on the substrate 24. The electronic components 26 are, for example, integrated circuits such as processors (i.e., semiconductor packages including semiconductor elements), and the electronic components 26 generate heat when in operation. The electronic components 26 are an example of heat generating members.

The electronic device 22 is, for example, a server. In addition to the electronic components 26 illustrated in FIG. 1, various components and connectors for memory 27 and the like are mounted on the substrate 24.

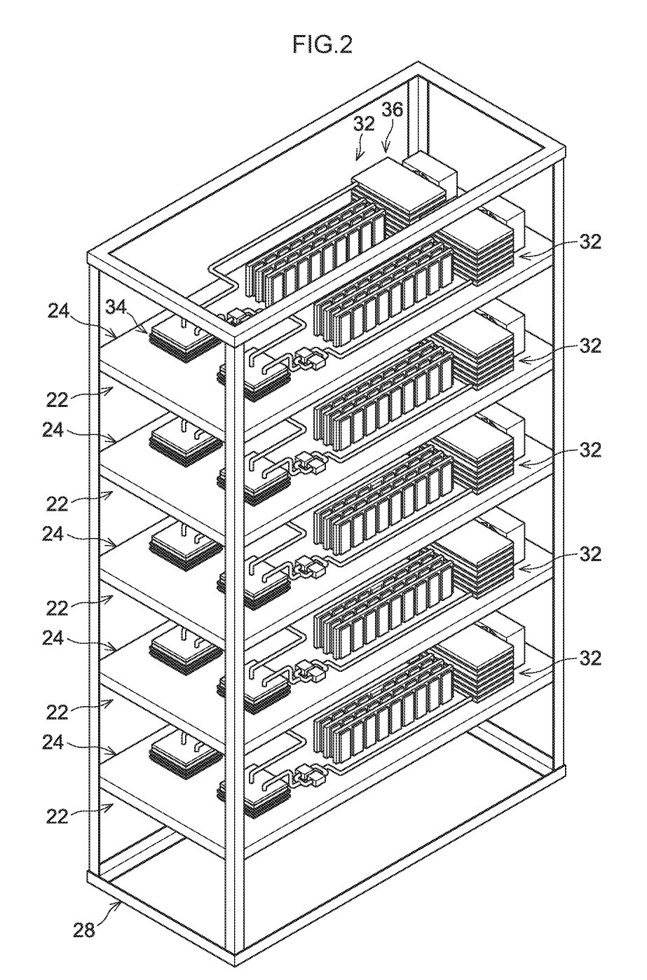

As illustrated in FIG. 2, plural of the electronic devices 22 might be loaded onto a rack 28. In such cases, there is no limitation to the array direction of the electronic devices 22 or the orientation of the electronic devices 22.

The electronic device 22 further includes a cooling device 32. The cooling device 32 is a device that receives heat from the electronic components 26, and removes the heat to the exterior of the electronic device 22. The cooling device 32 thus transports heat from the electronic components 26, and is an example of a heat transport device.

The cooling device 32 includes heat receiving members 34 that receive heat from the electronic components 26, and heat dissipating members 36 that dissipate heat to the exterior. The heat receiving member 34 and the heat dissipating member 36 are connected together by a coolant circulation path 38, which configures a structure in which coolant circulates between the heat receiving member 34 and the heat dissipating member 36.

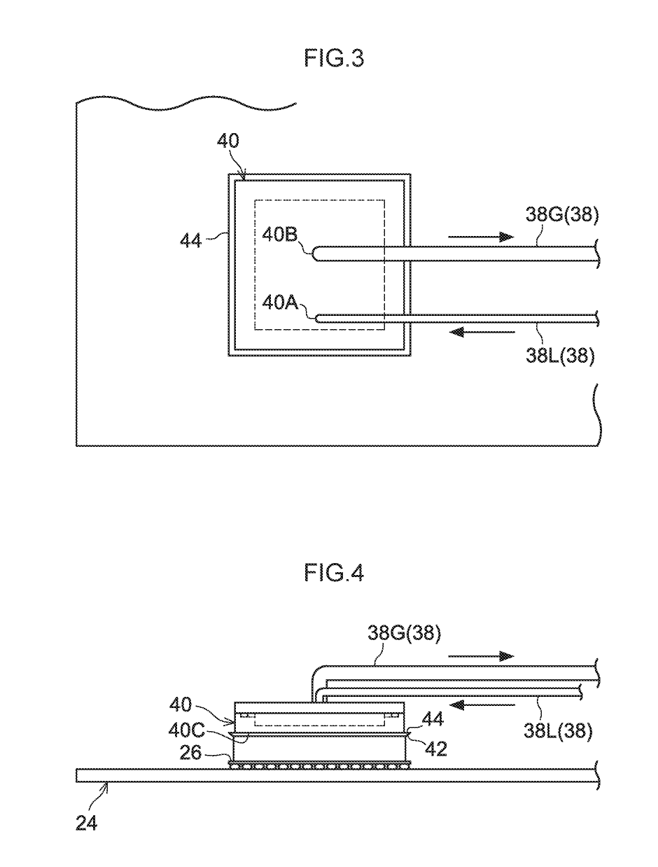

As illustrated in FIG. 3 and FIG. 4, each heat receiving member 34 includes a heat sink 40 provided with a coolant inlet 40A and a coolant outlet 40B. The heat sink 40 includes a heat receiving face 40C disposed facing the electronic component 26 across a heat spreader 42 and a heat transfer member 44.

In the present exemplary embodiment, the coolant turns to gas inside the heat sink 40 due to the heat from the electronic component 26. The gaseous coolant passes through the coolant circulation path 38 and flows to the heat dissipating member 36. Accordingly, a portion of the coolant circulation path 38 through which the gaseous coolant from the heat receiving member 34 flows toward the heat dissipating member 36 may be referred to as a vapor flow path 38G.

The heat sink 40 is, for example, a hollow member formed from copper, aluminum, stainless steel, or the like. Employing such metals as the material for the heat sink 40 enables heat from the electronic component 26 (heat generating member) to be efficiently transmitted to the coolant therein, and also enables a stable shape to be maintained with respect to internal pressure changes.

The heat spreader 42 acts to raise heat transfer efficiency between the electronic components 26 and the heat transfer member 44 (heat sink 40) by spreading the heat from the electronic components 26 that acts on the heat sink 40.

The heat transfer member 44 acts to fill unevenness in opposing faces of both the electronic component 26 and the heat sink 40 to place the electronic component 26 and the heat sink 40 in close contact with each other, and to increase the surface area over which heat is transmitted. The heat transfer member 44 may be referred to as a thermal interface material.

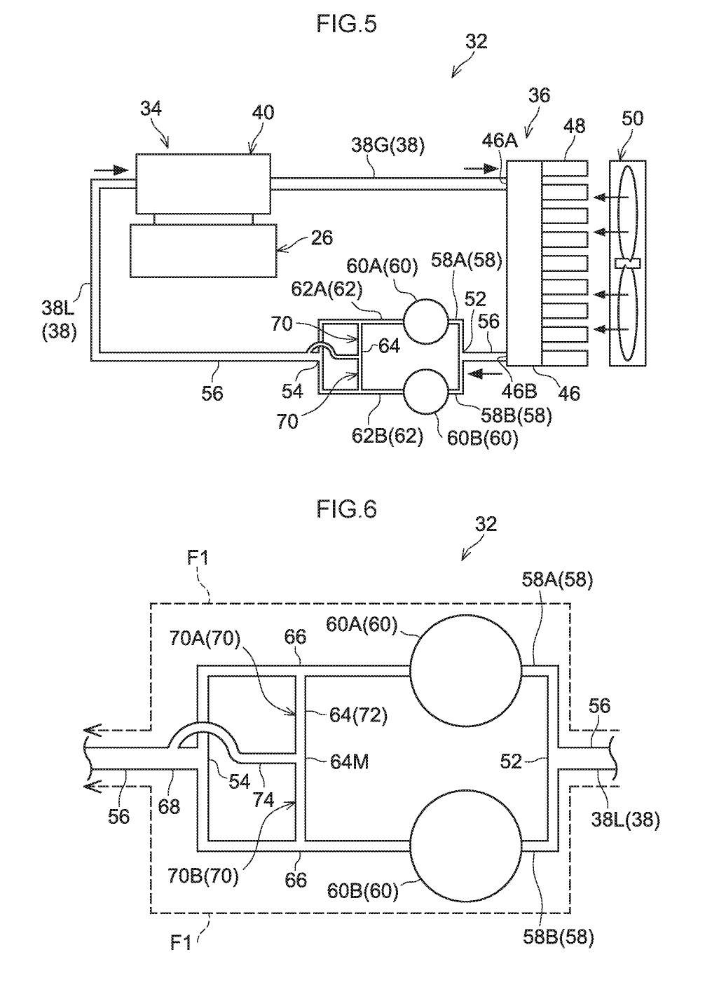

The heat dissipating member 36 includes an internal pipe 46 (see FIG. 5) including a coolant inlet 46A and a coolant outlet 46B. Plural heat dissipating fins 48 are attached around the internal pipe 46. Heat of the coolant flowing through the internal pipe 46 is dissipated through the heat dissipating fins 48, causing the coolant to condense (become liquid). The liquid coolant then returns to the heat receiving member 34 through the coolant circulation path 38 (i.e., a liquid flow path 38L). Accordingly, the portion of the coolant circulation path 38 in which liquid coolant flows from the heat dissipating member 36 to the heat receiving member 34 may be referred to as the liquid flow path 38L.

In the present exemplary embodiment, the flow path cross-sectional area of the vapor flow path 38G is no less than the flow path cross-sectional area of the liquid flow path 38L. Accordingly, coolant that has evaporated and increased in volume flows more readily through the vapor flow path 38G than through the liquid flow path 38L. Note that the flow path cross-sectional area of the vapor flow path 38G may also be approximately the same as the flow path cross-sectional area of the liquid flow path 38L.

In this manner, in the cooling device 32 of the present exemplary embodiment, a closed-loop circulation coolant system is formed in which the coolant is circulated between the heat receiving member 34 and the heat dissipating member 36 in order to transport heat. Note that configuration may be made in which some or all of the coolant moving from the heat receiving member 34 toward the heat dissipating member 36 is liquid, instead of all the coolant being gaseous. However, when the coolant moves from the heat receiving member 34 to the heat dissipating member 36 as a gas, latent heat of the coolant is utilized in heat transport, resulting in high heat transport efficiency.

In the present exemplary embodiment, cooling fans 50 are installed to the substrate 24. Moving air (an airflow) generated by the cooling fans 50 is supplied to the heat dissipating fins 48, thereby promoting heat dissipation through the heat dissipating fins 48.

As illustrated in detail in FIG. 6, in the coolant circulation path 38, part of the liquid flow path 38L is formed with plural split flow portions 58 (two in the example illustrated in FIG. 5 and FIG. 6) that split at a splitting junction 52. The split flow portions 58 merge at a merging junction 54. Namely, the coolant circulation path 38 includes the parallel split flow portions 58 in part, and a non-parallel main flow portion 56. Specifically, in the cooling device 32 of the present exemplary embodiment, the split flow portions 58 are provided at the liquid flow path 38L. When a distinction is made between the split flow portions 58 in the following explanation, the split flow portions 58 are referred to separately as the split flow portions 58A, 58B.

Each of the split flow portions 58 is provided with a pump 60. Driving the pumps 60 imparts kinetic energy to the coolant flowing in the coolant circulation path 38 (i.e., the split flow portions 58), enabling the coolant to be actively circulated through the coolant circulation path 38. When a distinction is made between the pumps 60 in the following explanation, the pumps 60 are referred to separately as the pumps 60A, 60B.

The pumps 60 are not particularly limited as long as they are capable of imparting kinetic energy to the coolant as described above such that the coolant circulates through the coolant circulation path 38. In the present exemplary embodiment, for example, pumps with spinning blades that move the coolant by creating a vortex to (such as centrifugal pumps or cascade pumps) are employed as the pumps 60. Such pumps are often capable of moving coolant both upstream and downstream of the pump from a stationary state.

The capacity of the pumps 60 is set such that coolant may be imparted with kinetic energy and caused to circulate through the coolant circulation path 38 even when only one of the pumps 60 is being driven. Accordingly, the electronic component 26 may be cooled, enabling an operational state of the electronic device 22 to be maintained, even in a state in which only one of the pumps 60 is being driven.

As illustrated in FIG. 5, a main pipe 62 is connected to an outlet side of each of the pumps 60, through which coolant is discharged. Namely, each main pipe 62 configures part of a split flow portion 58 of the coolant circulation path 38 (a portion at the outlet side). When a distinction is made between the main pipes 62 in the following explanation, the main pipes 62 are referred to separately as the main pipes 62A, 62B.

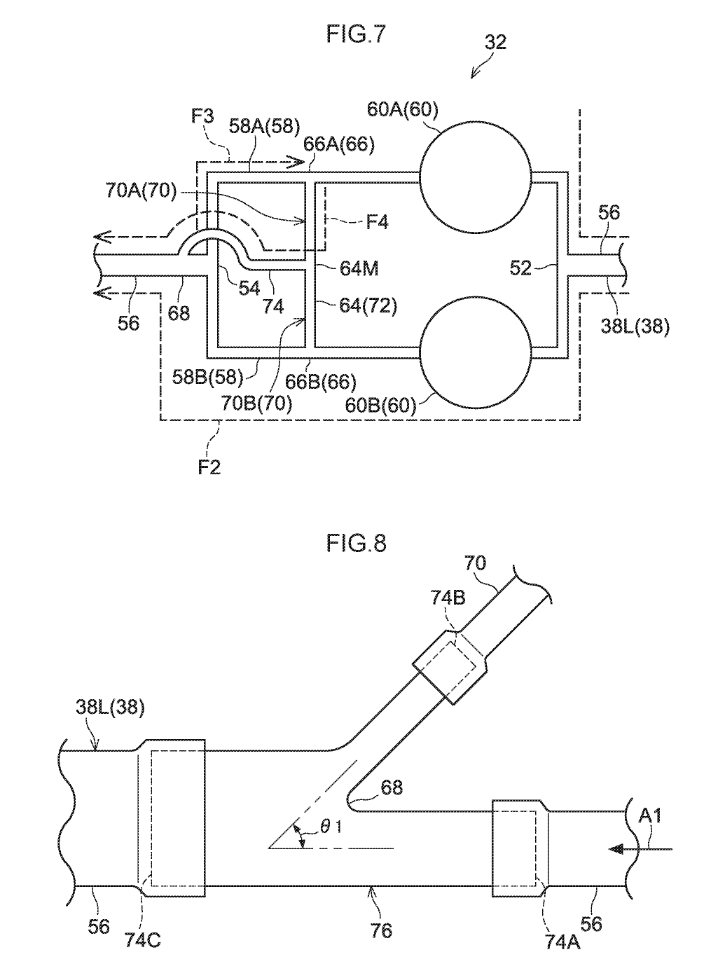

As illustrated in FIG. 6 and FIG. 7, in the present exemplary embodiment, branching junctions 66 are provided partway along each main pipe 62. A branch pipe 64 splits off from the main pipes 62 at the respective branching junctions 66. The branch pipe 64 places one main pipe 62A and the other main pipe 62B in communication with each other, and is an example of a communication flow path 72 that places the split flow portions 58 in communication with each other.

An intermediate point 64M of the branch pipe 64 is connected to the main flow portion 56 (i.e., to a connection point 68 downstream of the merging junction 54) by a connecting flow path 74. Namely, a bypass is formed by the branch pipe 64 and the connecting flow path 74 from partway along the split flow portions 58 (the branching junctions 66) to the main flow portion 56 (connection point 68). In other words, in the present exemplary embodiment, bypass flow paths 70 that form a bypass between the respective split flow portions 58 and the main flow portion 56 each have a structure including the communication flow path 72 and the connecting flow path 74. Moreover, part of the two bypass flow paths 70, specifically a portion from the intermediate point 64M to the connection point 68, is rendered common through the connecting flow path 74.

The flow path cross-sectional area of the bypass flow path 70 is no greater than the flow path cross-sectional area of either one of the split flow portions 58 (either one of the main pipes 62A, 62B).

The length of the bypass flow path 70 (the length from the respective branching junctions 66 to the connection point 68) is longer than the length from the branching junction 66 to the connection point 68 when following the coolant circulation path 38.

As illustrated in FIG. 8, a joint member 76 is provided at the connection point 68. The joint member 76 is formed with two inlets 74A, 74B and one outlet 74C. The main flow portion 56 is connected to the inlet 74A and the outlet 74C, and the joint member 76 forms a portion of the coolant circulation path 38 between the inlet 74A and the outlet 74C. The bypass flow path 70 is connected to the inlet 74B. Namely, the bypass flow path 70 is connected to the main flow portion 56 by the joint member 76 at the connection point 68.

As viewed from the upstream side (along the arrow A1 direction), at the connection point 68, a connection angle θ1 formed by the bypass flow path 70 with respect to the main flow portion 56 is from 0° to 90°.

The flow path cross-sectional area of the main flow portion 56 downstream of the connection point 68 is not less than the combined flow path cross-sectional area of the bypass flow path 70 and the main flow portion 56 upstream of the connection point 68.

In the present exemplary embodiment, purified water, or a solution of ethanol mixed with pure water of from 0.1 percent by mass ethanol up to, but not including, 5.0 percent by mass ethanol per 100 percent pure mass, may be employed as the coolant. A fluorine-based liquid may also be employed as the coolant. Such coolants are deaerated before being poured into the coolant circulation path 38 in a low pressure environment or at atmospheric pressure, and the coolant circulation path 38 is then sealed, so as to create a state in which the coolant is capable of circulating through the coolant circulation path 38.

Next, explanation follows regarding operation of the present exemplary embodiment.

When heat generated by operation of the electronic component 26 acts on the heat receiving member 34, the coolant inside the heat receiving member 34 evaporates.

In the cooling device 32 of the present exemplary embodiment, the coolant is circulated through the coolant circulation path 38 by driving the pumps 60. The two pumps 60A, 60B may, for example, be driven at the same time as each other. In such cases, by setting the output of the two pumps 60A, 60B to a similar extent, coolant discharged from the respective pumps 60A, 60B merges at the merging junction 54, as illustrated by the arrows F1 in FIG. 6.

The coolant then flows through the main flow portion 56, and flows into the heat receiving member 34 (heat sink 40). The coolant evaporated in the heat receiving member 34 has high thermal energy from the latent heat of vaporization. This gaseous coolant moves through the vapor flow path 38G to the heat dissipating member 36, thereby transporting the heat to the heat dissipating member 36.

In the present exemplary embodiment, the flow path cross-sectional area of the vapor flow path 38G is greater than the flow path cross-sectional area of the liquid flow path 38L. Namely, flow path resistance in the vapor flow path 38G is lower than flow path resistance in the liquid flow path 38L. Accordingly, coolant that has turned to gas inside the heat sink 40 flows more readily to the vapor flow path 38G than to the liquid flow path 38L.

At the heat dissipating member 36, heat is dissipated to the exterior (heat exchange takes place) from the coolant that has moved from the vapor flow path 38G to the heat dissipating member 36. The coolant therefore condenses (becomes liquid). The liquefied coolant flows through the liquid flow path 38L to the heat receiving member 34. Thus, the coolant circulating between the heat receiving member 34 and the heat dissipating member 36 enables continuous heat transportation from the heat receiving member 34 to the heat dissipating member 36.

In the present exemplary embodiment, in the coolant circulation path 38, the two pumps 60A, 60B are disposed in parallel. Accordingly, even if either one of the pumps is stopped, driving the other pump enables coolant to be circulated through the coolant circulation path 38. For example, in the example illustrated in FIG. 7, although the pump 60A is stopped, the pump 60B is being driven, maintaining the flow of coolant as illustrated by the arrow F2. Namely, the cooling device 32 is capable of transporting heat even when one of the pumps 60 is stopped, thus achieving redundancy in the pumps 60.

When the pump 60A is stopped, the pump 60A does not apply pressure to the coolant. Accordingly, as illustrated by arrow F3 in FIG. 7, some of the coolant that has flowed from the split flow portion 58B to the merging junction 54 may flow backward in the split flow portion 58A. In such cases, coolant discharged from the pump 60B that is being driven is flowing in the main flow portion 56 (downstream of the merging junction 54).

In the present exemplary embodiment, a pressure drop due to this flow occurs at the connection point 68 on the main flow portion 56. The bypass flow path 70 is connected to the main flow portion 56 at the connection point 68, and there is therefore also a pressure drop in the bypass flow path 70. Accordingly, as illustrated by the arrow F4, the portion of the coolant that has flowed into the split flow portion 58A returns to the main flow portion 56 through a bypass flow path 70A. In other words, the portion of the coolant attempting to flow backward toward the stopped pump 60A returns to the main flow portion 56, thereby enabling backflow of coolant to the stopped pump 60A to be reduced or suppressed. Coolant circulation is thereby maintained even when one of the pumps 60 is stopped without raising the capacity of the pumps 60 excessively, thereby enabling the redundancy of the pumps 60 to be secured.

Note that in the reverse of the above scenario, when the pump 60B is stopped, backflow of coolant discharged from the pump 60A that is being driven toward the pump 60B may be suppressed.

Moreover, in the present exemplary embodiment, since coolant backflow to the stopped pump 60 is reduced in a state in which one of the pumps 60 is stopped, there is no need to provide a valve member or the like. Namely, using a simple structure, it is possible to reduce coolant backflow to the stopped pump 60 when one of the pumps 60 is stopped.

Moreover, in a structure including a valve member, there is a concern of coolant stagnating in a case in which part of the coolant circulation path has been closed off by the valve member. However, no valve member is provided in the present exemplary embodiment, thereby preventing coolant stagnation. Namely, in this structure, coolant circulates readily between the heat receiving member 34 and the heat dissipating member 36, thereby enabling a decline in the function of the cooling device 32 to be prevented.

In addition, in a structure including a valve member, flow path resistance is increased by the valve member, and there are also concerns of foreign objects causing the valve member to jam. As a countermeasure to avoid such faults, the cross-sectional area may be increased over the entire coolant circulation path. However, increasing the diameter of the pipes forming the coolant circulation path results in the pipes being more difficult to bend, this being disadvantageous from the perspective of size reduction of the cooling device 32, and also reduces the degree of freedom in the layout of components mounted on the electronic device 22.

However, in the present exemplary embodiment, there is no need to enlarge the pipes forming the coolant circulation path, which contributes to a reduction in size of the cooling device 32. Moreover, there is a high degree of freedom in the layout of the components mounted on the electronic device 22.

In the first exemplary embodiment, the structure of the bypass flow paths 70A, 70B includes the branch pipe 64 (communication flow path 72) that places the split flow portions 58A, 58B in communication with each other, and also includes the connecting flow path 74 that connects the intermediate point 64M of the branch pipe 64 and the main flow portion 56 together. The two bypass flow paths 70A, 70B include a common portion along the connecting flow path 74, enabling a simpler structure than a structure in which the two bypass flow paths 70A, 70B are independent of each other all the way from the branching junctions 66 to the connection point 68.

The bypass flow path 70 is connected to the main flow portion 56 at the connection point 68 downstream of the merging junction 54. Downstream of the merging junction 54, the coolant flows in a single direction, toward the heat receiving member 34. Accordingly, coolant flow toward the main flow portion 56 may be reliably generated in the bypass flow path 70. Moreover, coolant returning to the main flow portion 56 through the bypass flow path 70 may be suppressed from flowing back toward the stopped pump 60 again.

Note that there is no limitation to the location of the connection point 68 as long as it is on the main flow portion 56. For example, the connection point 68 may be at a position close to the heat receiving member 34 in the liquid flow path 38L.

Moreover, the cooling device 32 of the present exemplary embodiment does not exclude a structure in which liquid coolant flows along a coolant flow path from the heat receiving member 34 to the heat dissipating member 36. In a structure in which liquid coolant flows along a coolant flow path from the heat receiving member 34 to the heat dissipating member 36, the connection point 68 may be provided to the coolant flow path from the heat receiving member 34 to the heat dissipating member 36. However, since the coolant flowing through the bypass flow path 70 has not passed the heat receiving member 34 and is at a low temperature, heat may be received more efficiently in the heat receiving member 34 if this coolant is sent to the heat receiving member 34.

The flow path cross-sectional area of the bypass flow path 70 is no greater than the flow path cross-sectional area of either one of the split flow portions 58 (i.e., either one of the main pipes 62A, 62B). Moreover, the length of the bypass flow path 70 (the length from the respective branching junctions 66 to the connection point 68) is longer than the length from the branching junctions 66 to the connection point 68 when following the coolant circulation path 38. Accordingly, flow path resistance in the bypass flow path 70 is greater than the flow path resistance in the coolant circulation path 38 in the range from the branching junctions 66 to the connection point 68. Accordingly, coolant discharged from the pump 60 that is being driven may be suppressed from flowing into the bypass flow path 70 unintentionally at the branching junction 66.

The flow path cross-sectional area of the main flow portion 56 downstream of the connection point 68 is no less than the combined flow path cross-sectional area of the bypass flow path 70 and the main flow portion 56 upstream of the connection point 68. Coolant that has flowed through the upstream main flow portion 56 and coolant that has flowed through the bypass flow path 70 merge at the connection point 68. Coolant may be prevented from pooling at the connection point 68 since the main flow portion 56 downstream of the connection point 68 has a large flow path cross-sectional area.

In the first exemplary embodiment, as described as an example above, the joint member 76 illustrated in FIG. 8 may be employed at the position of the connection point 68. In the joint member 76, as viewed from the upstream side in the coolant flow direction (along the arrow A1 direction), the connection angle θ1 formed by the bypass flow path 70 with respect to the main flow portion 56 is from 0° to 90°. If the connection angle θ1 is greater than 90°, some of the coolant flowing through the main flow portion 56 at the connection point 68 would be liable to enter the bypass flow path 70. However, in the present exemplary embodiment, the connection angle θ1 is from 0° to 90°, and therefore the flow of coolant from the bypass flow path 70 merging with the main flow portion 56 does not go against the flow of the coolant in the main flow portion 56. Coolant from the bypass flow path 70 accordingly flows smoothly into the main flow portion 56.

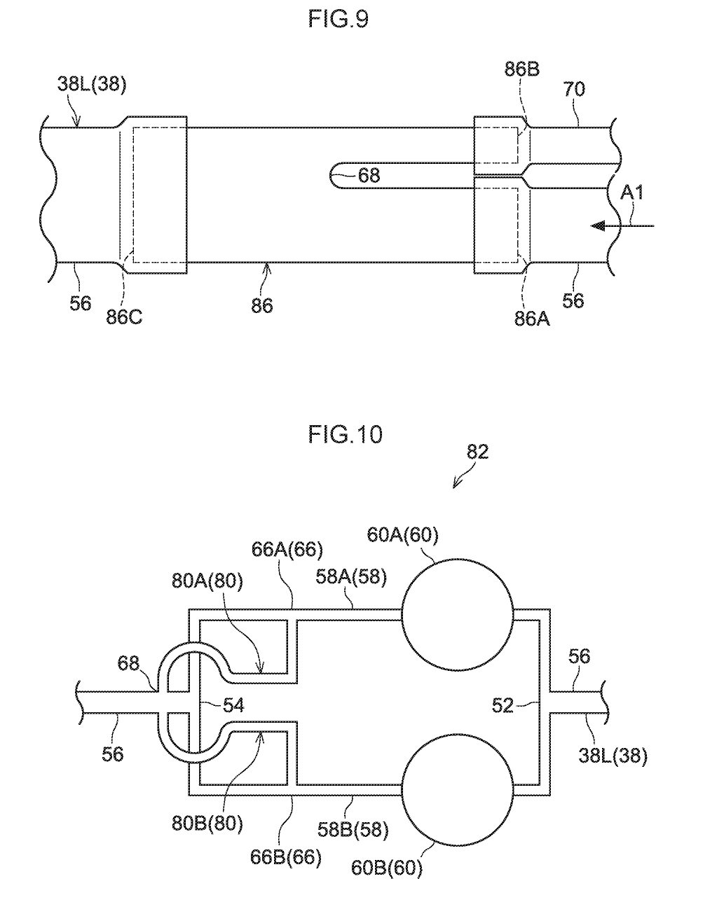

The joint member 86 illustrated in FIG. 9 may be employed instead of the joint member 76 illustrated in FIG. 8. Similarly, in the joint member 86 illustrated in FIG. 9, the main flow portion 56 is connected to an inlet 86A and an outlet 86C, and the bypass flow path 70 is connected to the inlet 86B.

In a structure employing the joint member 86, the bypass flow path 70 runs parallel to the main flow portion 56, such that the connection angle θ1 is substantially 0°. Coolant accordingly flows smoothly from the bypass flow path 70 into the main flow portion 56.

Employing the joint member 76 illustrated in FIG. 8 or the joint member 86 illustrated in FIG. 9 at the connection point 68 enables a predetermined connection angle θ1 of the bypass flow path 70 with respect to the main flow portion 56 to be maintained, enabling the connection state of the bypass flow path 70 to the main flow portion 56 to be reliably maintained.

Next, explanation follows regarding a second exemplary embodiment. In the second exemplary embodiment, elements, members, and so on that are similar to those of the first exemplary embodiment are allocated the same reference numerals, and detailed explanation thereof is omitted. Moreover, since the overall structure of the electronic device is the same as that of the first exemplary embodiment, illustration thereof is omitted.

A cooling device 82 of the second exemplary embodiment includes mutually independent bypass flow paths 80 at a split flow portion 58A side and at a split flow portion 58B side. Specifically, a bypass flow path 80A at the split flow portion 58A side splits from the split flow portion 58A at a branching junction 66A, and is connected to the main flow portion 56 at the connection point 68. Moreover, a bypass flow path 80B at the split flow portion 58B side branches from the split flow portion 58B at a branching junction 66B and is connected to the main flow portion 56 at the connection point 68.

In the cooling device 82 of the second exemplary embodiment, when one of the pumps 60 is stopped, backflow of coolant discharged from the other pump 60 that is being driven toward the stopped pump 60 may be reduced. Moreover, a simple structure suffices since a valve member or the like is not necessary in order to reduce such coolant backflow.

In the cooling device 82 of the second exemplary embodiment, the two bypass flow paths 80A, 80B are configured independently of each other all the way from the branching junctions 66A, 66B to the connection point 68. Accordingly, when coolant from the split flow portions 58A, 58B is returned to the main flow portion 56, coolant from other locations in the split flow portions 58A, 58B does not flow into the bypass flow paths 80A, 80B, enabling coolant to be returned to the main flow portion 56 efficiently.

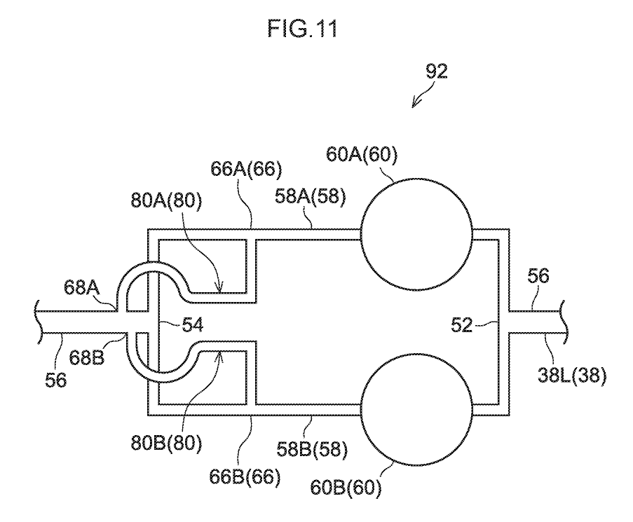

FIG. 10 illustrates a structure in which the two bypass flow paths 80A, 80B are connected to the main flow portion 56 at the single connection point 68 in the second exemplary embodiment. However, connection points 68A, 68B may be set at two different locations of the main flow portion 56 in the coolant flow direction, as in a cooling device 92 of a modified example of the second exemplary embodiment, illustrated in FIG. 11. In the structure illustrated in FIG. 11, the two bypass flow paths 80A, 80B are connected to the main flow portion 56 at the connection points 68A, 68B respectively.

In each of the exemplary embodiments described above, a cooling device is given as an example of a heat transport device. However, a heat transport device is not limited to the cooling device described above. For example, a heat transport device may be a device that dissipates heat from a coolant in a heat dissipating member in order to lower the temperature of the coolant to room temperature or lower, and transports the coldness of the coolant to a heat receiving member (this may be at room temperature or lower). Namely, in such a structure, the heat transport device functions as a cold transporting device.

As described above, in heat transport devices in which coolant is circulated in order to transport heat, a state in which heat may be transported is able to be maintained by disposing pumps in parallel in a coolant circulation path, and circulating coolant by a pump that is being driven when one of the pumps has been stopped.

In cases in which one of the pumps disposed in parallel is stopped, it is desirable to suppress backflow of the coolant from the driven pump to the stopped pump. Providing a valve member such as a three-way valve or a check valve to the coolant circulation path in order to reduce backflow leads to a more complex structure.

The disclosed aspect exhibits the effects of enabling coolant backflow from a driven pump to a stopped pump to be reduced with a simple structure when one pump is stopped in a structure in which pumps are disposed in parallel in a coolant circulation path.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A heat transport device comprising:
a heat receiving member that receives heat;
a heat dissipation member that dissipates heat;
a coolant circulation path that includes a main flow portion in which coolant flows and split flow portions where part of the main flow portion is split into a plurality of flow paths, and that causes coolant to circulate between the heat receiving member and the heat dissipating member;
pumps that are provided to the respective split flow portions; and
a bypass flow path that forms a bypass between the respective split flow portions on an outlet side of the pumps and the main flow portion.

2. The heat transport device of claim 1, wherein the bypass flow path includes:
a communication flow path that places the split flow portions in communication with each other; and
a connecting flow path that connects an intermediate portion of the communication flow path to the main flow portion.

3. The heat transport device of claim 1, wherein the bypass flow path branches from the respective split flow portions and is connected to the main flow portion.

4. The heat transport device of claim 1, wherein the bypass flow path is connected to the main flow portion downstream of a merging junction where the split flow portions merge.

5. The heat transport device of claim 1, wherein a flow path cross-sectional area of the bypass flow path is no greater than a flow path cross-sectional area of either one of the split flow portions.

6. The heat transport device of claim 1, wherein a flow path cross-sectional area of the main flow portion downstream of a connection point of the bypass flow path with the main flow portion is equal to or greater than the combined flow path cross-sectional area of the bypass flow path and the main flow portion upstream of the connection point.

7. The heat transport device of claim 1, wherein a length of the bypass flow path is equal to or greater than a length of the coolant circulation path from a branching junction of the bypass flow path from the split flow portion to a connection point of the bypass flow path to the main flow portion.

8. The heat transport device of claim 1, wherein as viewed from an upstream side, a connection angle formed by the bypass flow path with respect to the main flow portion is from 0° to 90°.

9. The heat transport device of claim 8, wherein the connection angle is substantially 0°.

10. The heat transport device of claim 1, further comprising a joint member that connects the bypass flow path to the coolant circulation path.

11. An electronic device comprising:
an electronic component;
a heat receiving member that receives heat from the electronic component;
a heat dissipating member that dissipates heat;
a coolant circulation path that includes a main flow portion in which coolant flows and split flow portions where part of the main flow portion is split into a plurality of flow paths, and that causes coolant to circulate between the heat receiving member and the heat dissipating member;
pumps that are provided to the respective split flow portions; and
a bypass flow path that forms a bypass between the respective split flow portions on an outlet side of the pumps and the main flow portion.
